(19) United States
(12) Patent Application Publication
(10) Pub. No.: US 2006/0072657 A1
(43) Pub. Date: Apr. 6, 2006

(54) Pulse width-modulated noise shaper

(75) Inventor: Bruno Johan Georges Putzeys, Herent (BE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/535,299

(22) PCT Filed: Oct. 29, 2003
(86) PCT No.: PCT/IB03/04795

§ 371 Date: May 17, 2005

(30) Foreign Application Priority Data
Nov. 22, 2002 (EP) 02079881.5

(51) Int. Cl. H03K 7/08

(52) U.S. Cl. 375/238

(57) ABSTRACT

A pulse width-modulated noise shaper (410) is described, which employs feedback from the power stage (260). Formation of the pulse width-modulated signal is done by applying a digital noise shaper (410) which uses feedback from the output of the power stage. Thus, any errors created by the power stage (260) are automatically corrected.

The present invention relates to a pulse width-modulated noise shaper. Such a noise shaper may be used, for instance, in a digital amplifier of an audio apparatus, for driving a speaker system.

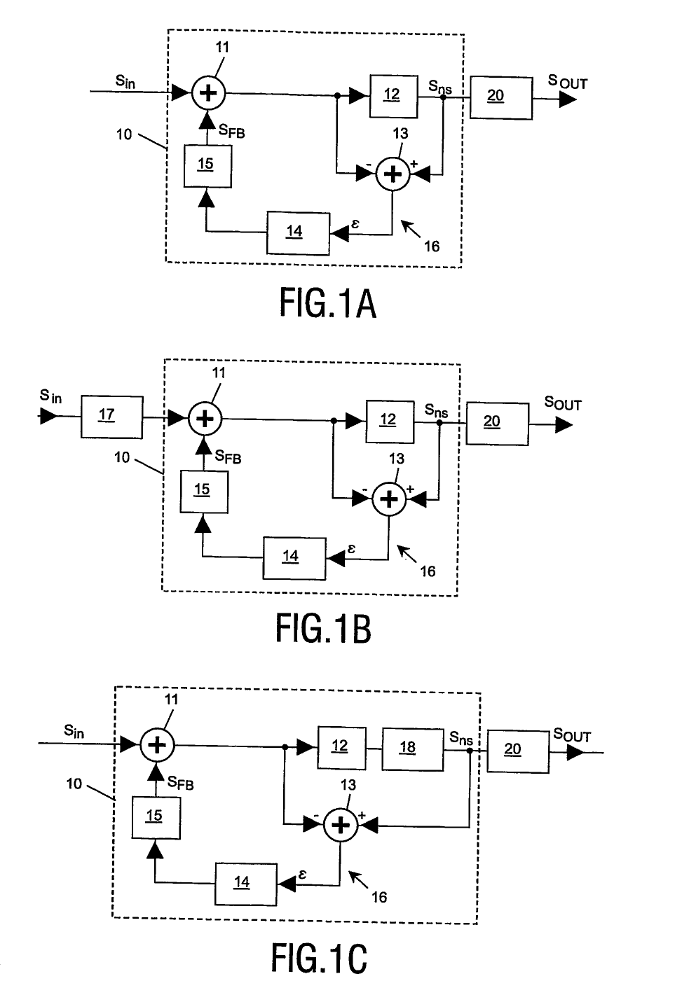

FIG. 1A is a block diagram schematically illustrating a conventional prior-art arrangement. Such conventional digital audio amplifiers typically comprise a noise shaper 10 operating in the z-domain, followed by a pulse width-modulation (PWM) circuit 20 which is of a type which samples in a uniform manner at a PWM repetition rate which is several times higher than the highest frequency to be reproduced. A digital signal Sᵢₙ is received at an input of an adder 11, an output of which is coupled to an input of a quantizer 12, which represents an approximation due to the fact that the edges of the PWM signal can only occur at predetermined moments. A comparator 13 compares the input and the output signal of the quantizer 12; any deviation or error ε is coupled to an input of a finite impulse response (FIR) filter 14, of which the output is coupled to the adder 11 through a delay 15, delaying the feedback signal sufficiently so that the adder receives a feedback signal S_{FB} corresponding to the previous calculation cycle. Thus, any errors caused by the quantizer 12 are corrected by the feedback path 16 of the noise shaper 10. The output signal Sₙₛ of the quantizer 12 is fed to the PWM circuit 20, which provides the output signal Sₒᵤₜ. In this case, the overall noise transfer function NTF of the noise shaper 10 can be expressed by formula (1):
NTF(z)=1+H(z)·z⁻¹ (1)
wherein H(z) represents the transfer function of the filter 14 in the z-domain.

A problem of this prior-art design is that the PWM circuit has a non-linear characteristic, which needs to be compensated if it is desired to achieve a good distortion specification and a good noise specification. A further problem of this prior art design is that errors in the subsequent class D power stage are not corrected.

One prior-art approach for compensating the non-linearity of the PWM circuit is shown in FIG. 1B. In this case, an error compensation circuit 17 is arranged before the noise shaper 10. The error compensation circuit 17 contains a model of the distortion caused by the PWM circuit 20, and introduces corrective measures before noise shaping.

A disadvantage of this prior-art design is that noise demodulation occurs as a result of intermodulation in the PWM circuit. The band above the band of interest, for example above the audio band, contains a continuous band of noise-shaped quantisation noise. The PWM repetition rate f_{SW} and/or any of two frequency components f₁ and f₂ of the noise can combine to form an intermodulation frequency fₚ=|n·f₁+m·f₂+p·f_{SW}|, n, m, p being positive and/or negative integers, the frequency f_{P} falling within the band of interest. This limits the amount of noise-shaping that can be applied and hence the signal-to-noise ratio which can be practically attained.

Another prior-art approach for compensating the non-linearity of the PWM circuit is shown in FIG. 1C. In this case, an error compensation circuit 18 is arranged inside the noise shaper 10, at the output of quantizer 12. The error compensation circuit 18 contains a model of the low-frequency portion of the distortion caused by the PWM circuit 20, and introduces corrective measures before feeding the noise shaper output signal Sₙₛ back to the comparator 13. This arrangement allows the distortion as well as the intermodulation characteristic of the PWM circuit 20 to be taken into account, allowing the use of higher order noise shapers.

An example of this approach is disclosed in, for instance, U.S. Pat. No. 5,548,286.

A disadvantage of this prior-art design is that the model is highly complex.

A common disadvantage of the prior-art approaches of FIGS. 1B and 1C is that they are only capable, to some extent, of compensating predictable errors due to the non-linearity of the PWM process, whilst they are incapable of compensating errors occurring in the subsequent class-D power stage as these errors are essentially unpredictable.

It is an object of the present invention to provide a PWM noise shaper which is capable of reducing errors in subsequent stages coupled to the noise shaper.

The invention is defined by the independent claims. The dependent claims define advantageous embodiments.

By incorporating the pulse width modulation circuit in the feedback loop, errors caused by this circuit are compensated. In an embodiment the power stage is also included in the feedback loop.

In prior-art designs of a noise shaper, a power output stage may be arranged, receiving the output signal Sₒᵤₜ of the PWM circuit. Such power output stages may cause errors, which are essentially unpredictable. As noted earlier, prior-art noise shapers are not capable of compensating such errors. According to an embodiment of the present invention, the feedback path of the noise shaper takes the output signal of this power output stage, or a signal derived therefrom, as its input signal.

It is noted that U.S. Pat. No. 5,898,340 describes in general terms a class-D amplifier comprising a digital processing unit which processes a signal derived from the output voltage in order to provide corrected PWM drive signals for the output switches. This publication, however, does not describe how the digital processing unit operates.

It is further noted that EP-1.104.094 describes a control system for a class-D amplifier, wherein the switching output signal is converted from analog to digital and fed back to the input of the control system. However, before A/D conversion, the signal is always filtered to the bandwidth of the frequency band of interest. Such a filter operation introduces a delay, which precludes efficient error correction in the higher frequency portion of the pass band of this filter. Furthermore, this system comprises distinct sections like a control loop driving a noise-shape pulse modulator which in turn controls the power stage. In such a design, the quantisation noise from the modulator is reduced by the modulator's own loop gain and the gain of the “outer control loop”, whereas power stage errors are only reduced by the gain of the outer control loop. In contrast, an embodiment of the present invention employs only one single loop which performs the function of a noise shaper for the pulse modulation as well as the function of control loop for the output stage errors.

The pulse width-modulated noise shaper according to the present invention may be applied in an electronic apparatus, such as, for example, a class-D audio amplifier. It allows the use of a cost-effective and low power-consuming class-D amplifier while realising excellent performance.

These and other aspects, features and advantages of the present invention will be further explained by the following description of exemples of embodiments of a PWM noise shaper according to the present invention with reference to the drawings, in which identical reference numerals indicate the same or similar parts, and in which:

FIGS. 1A-C are block diagrams schematically illustrating prior-art designs of a PWM noise shaper;

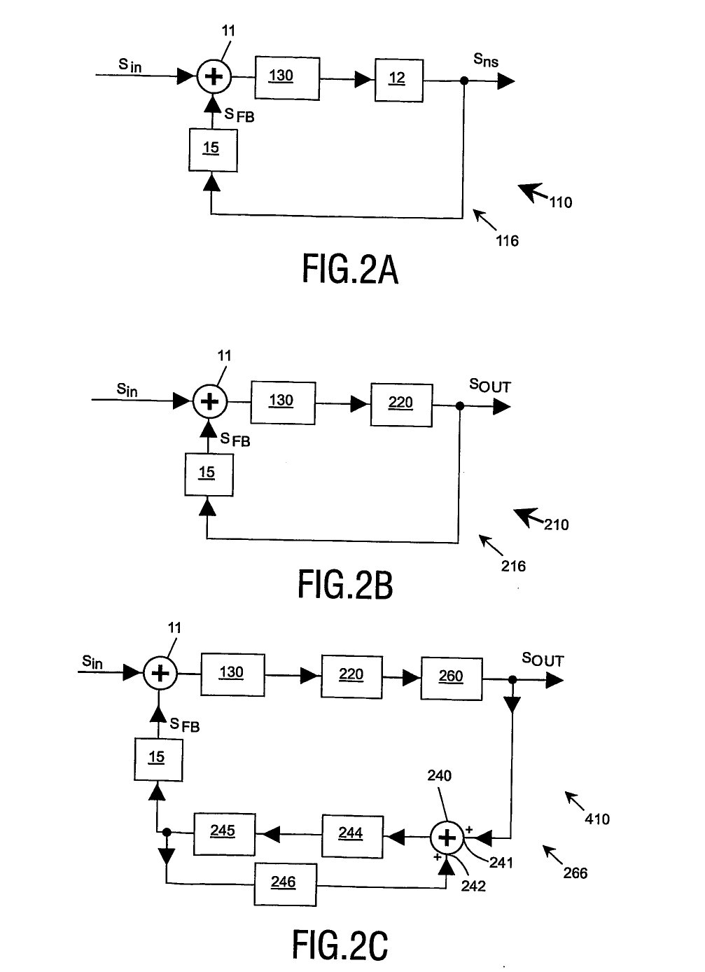

FIG. 2A schematically illustrates one aspect of a noise shaper designed in accordance with the present invention;

FIG. 2B schematically illustrates an embodiment of a noise shaper circuit which includes a PWM circuit;

FIG. 2C schematically illustrates an embodiment in accordance with the present invention which includes a PWM circuit and a power stage; and

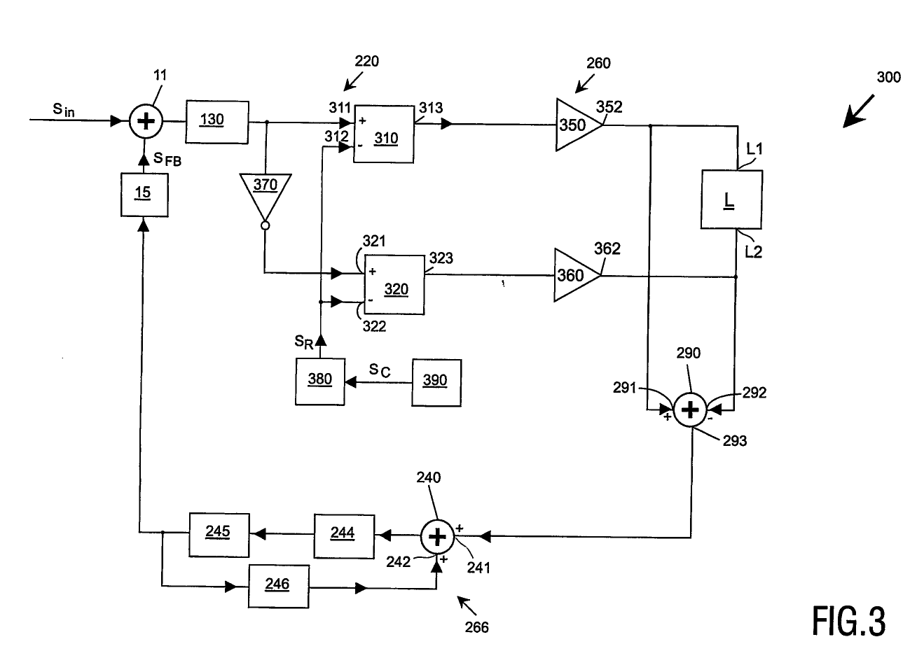

FIG. 3 schematically illustrates an embodiment of a part of an amplifier having a noise shaper in accordance with the present invention.

The design of a PWM noise shaper in accordance with the present invention will be explained with reference to FIGS. 2-3. FIG. 2A shows a noise shaper 110. This noise shaper 110 comprises an adder 11, a quantizer 12, a feedback path 116 containing a delay 15. When comparing this noise shaper 110 with the noise shaper 10 of FIG. 1A, it is immediately clear that the comparator 13 and the filter 14 have been omitted: the feedback path 116 feeds back a feedback signal S_{FB} derived from the noise-shaped output signal Sₙₛ, to the input adder 11, through the delay 15. The sampling frequency of the digital signal Sᵢₙ received at an input of the adder 11 is made equal to the PWM repetition rate by means of an upsampling filter or a sample-rate converter (not shown).

Furthermore, the noise shaper 110 comprises an infinite impulse response (IR) filter 130, coupled between the output of adder 11 and the input of quantizer 12. This filter 130 can be designed in such a way that the noise transfer function of the noise shaper 110 is similar to the noise transfer function NTF of the noise shaper 10 of FIG. 1A, when the following formula (2) is met:

$$K ( z ) = \frac{z \cdot ( NTF ( z ) - 1 )}{NTF ( z )} \qquad ( 2 )$$

wherein K(z) represents the transfer function of the IIR filter 130.

It is noted that the transfer function of the input signal Sᵢₙ to the output signal Sₙₛ is no longer unity as in prior-art noise shapers such as shown in FIG. 1A, but is affected by the filter 130 in the signal-feedback loop. In order to correct this, a correction circuit may be arranged before the input of the noise shaper 110 (not shown in FIG. 2A for the sake of simplicity), as will be clear to a person skilled in the art.

The RR filter 130 has a lowpass characteristic and a long impulse response. It is possible to operate the IHR filter 130 at a higher sample rate than the PWM repetition rate fsw.

It is possible to realise an adapted IR filter which has substantially the same absolute frequency response and impulse response as the above described filter, but which operates at a higher sampling frequency than the PWM repetition rate f_{sw}. If it operates at a frequency which is a factor of r higher than the PWM repetition rate f_{sw}, then by a so called “matched-z” transform the poles and zeros of the adapted filter are found by raising the poles and zeros of the original filter to the power of 1/r, as will be clear to a person skilled in the art. Gain correction can be set so as to keep the DC gain the same, as will also be clear to a person skilled in the art.

In a noise shaper, a PWM circuit (such as circuit 20 of FIG. 1A) would be arranged at the output of the noise shaper 110. The PWM circuit generates PWM output samples at a rate called the PWM repetition rate f_{sw}.

If, for example, 6 bits are used to code the pulse width of the output samples, then 2⁶=64 different pulse widths can be generated by the PWM circuit. This may be done by using a clock frequency f_{ck} of 64 times the PWM repetition rate. By selecting a pulse width between 0 and 64 clock periods, the desired number of different pulse widths can be generated by this PWM circuit. Such a PWM circuit also performs the function of the quantizer 12 of FIG. 2A, so there is no separate quantizer required in this case.

Since it is possible to operate the IIR filter 130 at a higher sample rate than the PWM repetition rate f_{sw}, it is possible to select the operating frequency of the IIR filter 130 to be equal to the clock frequency f_{ck} of the PWM circuit, and to include a PWM circuit with the noise shaper by placing a PWM circuit 220 inside the feedback loop of the noise shaper. An important advantage is that the feedback path 116 of the noise shaper feeds back a PWM circuit's output signal Sₒᵤₜ and not an error signal, as is the case with the prior art. This embodiment of the present invention is illustrated in FIG. 2B, which schematically illustrates an embodiment of a pulse width-modulated noise shaper (PWMNS) 210 of the present invention. In this embodiment, the output signal Sₒᵤₜ, fed back to the adder 11, is a digital signal in the form of a pulse width-modulated signal. This signal can easily be converted into the same digital format as the digital signal Sᵢₙ for executing the addition in the adder 11. While having a design which is hardly more complicated than the design of prior-art noise shapers, this PWMNS 210 has a performance which is much better than any prior-art design, especially with respect to the signal-to-noise ratio SNR, because now it is possible to achieve the maximum SNR which is theoretically attainable in a noise shaper without PWM.

Next to the PWM circuit 220, also the power stage, for example a class-D audio power stage 260, may be included in the feedback loop of a PWMNS 410 as shown in FIG. 2C. The power stage includes an output filter which, for example, is an LC filter. The output filter integrates the pulse width-modulated signal amplified in the power stage, resulting in an analog output signal Sₒᵤₜ, present at the output terminal of the PWM noise shaper.

In a prior-art design, such as illustrated in FIG. 1A, taking feedback from the output of the power stage 260 would involve the necessity of converting the feedback signal at a sample rate equal to the PWM repetition rate f_{sw}, which involves long delay times. More particularly, any analog-to-digital converter (ADC) in the feedback loop would be required to operate at the PWM repetition rate f_{sw}. Any frequency components outside the Nyquist band of this ADC would have to be removed prior to A/D conversion, otherwise some of these components may alias back into the band of interest. Alternatively, if the ADC were to operate at a higher sampling rate, the subsequent conversion of its output signal to a sample rate of the PWM repetition rate f_{sw} would again require the removal of any frequency components outside the nyquist band permitted by the PWM repetition rate f_{sw}. Such a removal would produce a delay of several samples long, which would make synthesis of an efficient and stable loop impossible. Any prior-art proposal which does not take the above into account, cannot result in a reliably working device.

In the case of the PWMNS 410 in an embodiment of the present invention, this disadvantage is absent. Thanks to the fact that the sample rate of the feedback path is identical to the clock frequency f_{ck} of the PWM circuit, the required conversion from analog domain to digital domain can be obtained by an analog noise shaper and a relatively simple A/D converter, of which the resolution does not need to be higher than 3 bits, as illustrated in FIG. 2C. Particularly, the feedback path 266 can be implemented similar to common audio ADCs, practically all of which are nowadays designed as delta-sigma converters.

In the feedback path 266, an analog adder 240 has a non-inverting input 241 constituting the input of the feedback path 266. An analog filter 244 receives the output signal from the adder 240. An analog-to-digital converter (ADC) 245 receives the output signal from the filter 244. The ADC 245 provides the feedback signal to be used as input signal for input adder 11 in the PWMNS 410 of FIG. 2C. Through a digital-to-analog (D/A) converter 246, the output signal of the ADC 245 is fed back to a second non-inverting input 242 of the adder 240. The D/A converter 246 also only needs to have a resolution of 3 bits, equal to the resolution of the ADC 245.

The ADC 245 does not require a high resolution. Although, in principle, the resolution may be as low as 2 bits, a resolution of 3 bits is preferred. A higher resolution, of for instance 4 bits, is possible, but not necessary. It is noted that the noise inside the band of interest, i.e. the accuracy, may be improved by selecting a higher-order loop filter 244, whereas the out-of-band noise (determined by the resolution of the loop) of a 3-bit ADC was found to be sufficiently low so as not to affect the performance of the PWMNS 410.

No severe requirements are imposed on the performance of the ADC 245. In the case of application in an audio device, only the performance in the audio band is of interest. Therefore, it is sufficient if the noise level of the feedback path 266 is good in the audio band.

The feedback path 266 is preferably operated to sample at the clock frequency f_{ck} of the PWM circuit 220. A lower frequency is possible, too, but then the requirements imposed on the loop filter 244 become more severe. Furthermore, a delta-sigma analog-to-digital converter constituted by adder 240, filter 244, ADC 245, and D/A converter 246, is designed to be a second-order delta-sigma analog-to-digital converter. These requirements, which can simply be met by a person skilled in the art, are sufficient to obtain a performance of 120 dB dynamic range in the audio band. A higher dynamic range is possible, but hardly useful, since the analogue components of the device are usually unable to cope with such a dynamic range.

By way of example, FIG. 3 illustrates an embodiment of a part of an amplifier 300, which uses the PWMNS 410 of FIG. 2C, wherein the PWM circuit 220 is implemented in combination with a first power stage 350 and a second power stage 360 as a 3-level PWM system operating at a PWM repetition rate f_{sw} of 384 kHz.

The PWM circuit 220 comprises two comparators 310 and 320 and an inverter 370. The first comparator 310 has a first non-inverting input 311 receiving the output signal from the main filter 130. The second comparator 320 has a first non-inverting input 321 receiving an inverted version of the output signal from the main filter 130, in this case through an inverter 370. The first and second comparators 310 and 320 have second inverting inputs 312 and 322, respectively, receiving a triangular reference signal SR from a reference signal generator 380. The first comparator 310 has an output 313 connected to an input of the first power stage 350, while the second comparator 320 has an output 323 connected to an input of the second power stage 360. The reference signal generator 380 receives a clock signal S_{C}, which has a clock frequency f_{ck}, from a clock signal generator 390.

By way of example, the triangular reference signal S_{R} may have a frequency of 384 kHz, and the clock signal S_{C} may have a clock frequency of 24.576 MHz. Exactly 2⁶=64 clock periods of the clock signal S_{C} fit within one period of the PWM repetition rate of 384 kHz. The triangular reference signal Sᵣ has a positive slope consisting of 32 equidistant steps, and a negative slope of 32 equidistant steps, each step having a duration of one clock period. In this way, the comparators 310, 320 have at their outputs a pulse width-modulated signal with a repetition rate of 384 kHz and a pulse width between 0 and 64 clock periods in dependence on the signals at their respective inputs 311, 321.

The class-D power stages 350 and 360 have output terminals 352 and 362, respectively, connected to input terminals L1 and L2, respectively, of a load L. The output terminals 352 and 362, respectively, are also connected to a non-inverting input 291 and an inverting input 292, respectively, of an adder 290, whose output 293 is coupled to the first input 241 of the adder 240 of the feedback path 266.

With the design of FIG. 3, with a clock frequency as low as 24.576 MHz, a THD+N (the ratio of desired signal content to non-desired signal content as measured within the band of interest) of 120 dB is possible, at a modulation index of 92%.

The amplifier 300 may further comprise signal processing circuitry, which amongst others provides a conversion of the signal present at a connector of the amplifier, into the digital signal Sᵢₙ.

Thus, the present invention succeeds in providing a PWM noise shaper, which employs feedback from the power stage. Formation of the PWM signal is done by using a digital noise shaper, of which the feedback takeoff point is in the analog domain, wherein the feedback loop includes an ADC with a short delay time and wide bandwidth. Thus, any errors created by the power stage are automatically corrected. An important advantage is that all components, with the exception perhaps of the class-D power stages 350 and 360, can be integrated on one chip.

It should be clear to a person skilled in the art that the present invention is not limited to the exemples of the embodiments discussed above, but that various variations and modifications are possible within the protective scope of the invention as defined in the appending claims.

For instance, it is possible that individual ADC feedback loops are provided for each of the class-D power stages 350 and 360. It is also possible that the outputs of said class-D power stages 350 and 360 are individually converted to digital signals by separate AD converters and that the resulting digital signals are subtracted digitally.

Furthermore, instead of a full-bridge implementation as illustrated in FIG. 3, it is also possible that the present invention is implemented by a half-bridge design, comprising only one class-D power stage.

Furthermore, the output signal present at the output terminals 352, 366 of the power stages 350, 360, respectively, is normally filtered by a suitable filter, typically an LC filter, before being applied to the load L, typically a loudspeaker. The frequency response of the filter is strongly dependent on the load. In order to ensure a preferably flat frequency response of this LC filter independent of the load and to remove any non-linearities thereof, the feedback path 266 may take additional input from the filtered output signal. Again, however, this will be an analog signal.

In the embodiment illustrated in FIG. 3, the power stage is shown as a full bridge. This allows the advantage of doubling the effective sample rate with respect to the physical switching frequency when both halves are controlled independently so that, during each cycle, the circuit is switched four times instead of two times (class BD), as will be clear to a person skilled in the art. This enlarges the loop gain and improves the signal-to-noise ratio. However, the present invention can also be implemented by a half-bridge implementation (class AD).

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. Use of the article “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

1. A pulse width-modulated noise shaper (210; 410), comprising:
an input adder (11) having a first input for receiving an input signal (Sᵢₙ), and a second input;
an output terminal;
a main filter (130) having an input coupled to receive an output signal from said input adder (11);
a pulse width modulation circuit (220) having an input coupled to receive a signal derived from an output of said main filter (130), an output coupled to an output terminal of the pulse width-modulated noise shaper, and operable at a clock fequency (f_{ck});
a feedback path (216; 266) coupled between the output terminal and the second input for generating a feedback signal (S_{FB}) and for feeding this feedback signal (S_{FB}) back to the second input, the feedback path (216; 266) and the main filter (130) being operable at a clock frequency of at least the clock frequency (f_{ck}) of the pulse width modulation circuit (220).

2. A pulse width-modulated noise shaper (210; 410) according to claim 1, further comprising a power stage (260), coupled between the output of the pulse width modulation circuit (220) and the output terminal, the feedback path (266) comprising means for analog-to-digital conversion (240, 244, 245, 246).

3. A pulse width-modulated noise shaper (210; 410) according to claim 2, wherein the means for analog-to-digital conversion (240, 244, 245, 246) comprise:
a second adder (240) having a first input (241) coupled to the output terminal;
a loop filter (244) having an input coupled to receive an output signal from said second adder (240);
an analog-to-digital converter (245) having an input coupled to receive an output signal from said loop filter (244), and an output coupled to the second input of the input adder (11);
and a digital-to-analog converter (246) having an input coupled to receive an output signal from the analog-to-digital converter (245), and an output coupled to a second input (242) of the second adder (240).

4. A pulse width-modulated noise shaper (210; 410) according to claim 3, wherein said analog-to-digital converter (245) has a resolution of less than 5 bits.

5. A pulse width-modulated noise shaper (210; 410) according to claim 2, wherein said pulse width modulation circuit (220) and said power stage (260) comprise:
a first branch comprising a first comparator (310), and a first class-D power stage (350) having an input coupled to receive an output signal from said first comparator (310), said first comparator (310) having a first input (311) coupled to receive the signal derived from the output signal of said main filter (130), and said pulse width modulation circuit (220) further comprising a reference signal generator (380) having an output coupled to a second input (312) of said first comparator (310).

6. A pulse width-modulated noise shaper (210; 410) according to claim 5, wherein said pulse width modulation circuit (220) and said power stage (260) further comprise:
a second branch comprising a second comparator (320), and a second class-D power stage (360) having an input coupled to receive an output signal from said second comparator (320);
said second comparator (320) having a first input (321) coupled to receive a signal which is inverted with respect to the signal derived from the output signal of said main filter (130), and said reference signal generator (380) having an output coupled to a second input (322) of said second comparator (320).

7. A pulse width-modulated noise shaper (210; 410) according to claim 6, wherein said feedback path (266) comprises means (290) for subtracting a feedback signal derived from said first class-D power stage (350) output (352) and a feedback signal derived from said second class-D power stage (360) output (362).

8. A digital-to-analog converter (300) comprising a pulse width-modulated noise shaper (210; 410) according to claim 1.

9. An electronic apparatus comprising a pulse width-modulated noise shaper (210; 410) according to claim 1 and signal processing circuitry for providing the input signal (Sᵢₙ) in a digital format.
